(19) United States
(12) Patent Application Publication
(10) Pub. No.: US 2024/0224563 A1
(43) Pub. Date: Jul. 4, 2024

(54) LIGHT EMITTING DISPLAY

(71) Applicant: LG Display Co., Ltd., Seoul (KR)

(72) Inventors: Howon CHOI, Paju-si (KR); Taehyeon KIM, Paju-si (KR)

(21) Appl. No.: 18/474,791

(22) Filed: Sep. 26, 2023

(30) Foreign Application Priority Data
Dec. 28, 2022 (KR) 10-2022-0186640

(51) Int. Cl. H10K 50/115; H10K 59/122; H10K 59/80

(52) U.S. Cl. CPC H10K 50/115; H10K 59/122; H10K 59/80515; H10K 59/80521; H10K 59/878

(57) ABSTRACT

The present disclosure relates to a light emitting display in which the light extracting efficiency is improved by using nano patterns (or nano particles). A light emitting display includes a substrate including a first pixel and a second pixel. The light emitting display includes a buffer layer on the substrate. The light emitting display includes a nano layer on the buffer layer. The light emitting display includes an anode electrode on the nano layer. The light emitting display includes a reflective layer between the buffer layer and the anode electrode.

### CROSS-REFERENCE TO RELATED APPLICATIONS

This application claims the benefit of the Republic of Korea Patent Application No. 10-2022-0186640 filed on Dec. 28, 2022, which are hereby incorporated by reference in its entirety.

### BACKGROUND

### Technical Field

The present disclosure relates to a light emitting display in which the light extracting efficiency is improved by using nano-patterns (or nano-particles).

### Description of the Related Art

Recently, various type of display such as the cathode ray tubes (CRTs), the liquid crystal displays (LCDs), the plasma display panels (PDPs) and the electroluminescent displays have been developed. These various types of display are used to display image data of various products such as computer, mobile phones, bank deposit and withdrawal devices (ATMs), and vehicle navigation systems according to their unique characteristics and purposes.

Among display devices, a light emitting display has advantages such as a wide viewing angle, excellent contrast ratio, and a fast response speed, and thus has attracted attention as a next-generation display. A light emitting element used in a light emitting display generally includes an emission layer made of organic or inorganic material between an anode electrode and a cathode electrode.

### BRIEF SUMMARY

The inventors have realized that in a structure of a light emitting display actually implemented in the related art, an optical wavelength may be formed between a transparent conductive layer used for an anode electrode or a cathode electrode having a relatively high refractive index and an emission layer. Therefore, about 50% of the light generated in the emission layer may be trapped inside the optical waveguide, and 30% of the light may be trapped inside the device due to total reflection caused by the difference in refractive index between the glass substrate and the air layer of environment. As a result, the amount of light finally emitted toward the user may be reduced down to about 20%.

In order to overcome this technical problem, the inventors have realized that it is beneficial to develop a light emitting display simplifying a manufacturing process, reducing manufacturing cost, and improving light extraction efficiency. In addition, it is beneficial for a light emitting display device having improved light extraction efficiency while reducing power consumption.

Various embodiments of the present disclosure address the various technical problems in the related art including the above-identified problem. For instance, some embodiments of the present disclosure provide a light emitting display having improved light extraction efficiency with a nano-structure. Some embodiments of the present disclosure provide a light emitting display having higher luminance with the same power consumption, and providing the same luminance with lower power consumption, so as to provide a light emitting display having improved light extraction efficiency with low power consumption. Some embodiments of the present disclosure provide a light emitting display including nano-structures having a constant density distribution and high density without requiring a separate nanomaterial forming process.

In one embodiment, a light emitting display comprises: a substrate including a first pixel and a second pixel; a buffer layer on the substrate; a nano layer on the buffer layer; an anode electrode on the nano layer; and a reflective layer between the buffer layer and the anode electrode.

In one embodiment, the reflective layer covers the nano layer, and disposed under the anode electrode.

In one embodiment, the reflective layer is disposed under the nano layer and on the buffer layer.

In one embodiment, the light emitting display further comprises: a lower conductive layer disposed between the reflective layer and the buffer layer.

In one embodiment, the lower conductive layer comprises: a transparent conductive material including at least one of indium-tin-oxide and indium-zinc-oxide.

In one embodiment, the nano layer includes: first nano-particles having a first size; and second nano-particles having a second size smaller than the first size.

In one embodiment, the light emitting display further comprises: a third pixel on the substrate. There is no nano layer at the third pixel.

In one embodiment, the nano layer includes at least one of indium-tin-oxide and indium-zinc-oxide.

In one embodiment, the nano layer includes: a nano-based layer; and nano-particles having protrusion shape formed on the nano-based layer.

In one embodiment, the nano-based layer and the nano-particles include same material.

In one embodiment, the nano layer includes: a plurality of nano-particles; and residual thin layers dispersed in some spaces between the nano-particles.

In one embodiment, the residual thin layers include same material as the nano-particles.

In one embodiment, the light emitting display further comprises: a planarization layer under the buffer layer.

In one embodiment, the light emitting display further comprises: a driving layer disposed between the planarization layer and the substrate, and including driving element connected to the anode electrode.

In one embodiment, the light emitting display further comprises: a bank covering edge portions of the anode electrode, exposing central area of the anode electrode, and defining an emission area; an emission layer on the bank and the anode electrode; and a cathode electrode on the emission layer.

For the light emitting display according to the present disclosure, the extraction efficiency of light generated from the emission layer can be improved by forming the nano-structure on the anode electrode. In addition, in constructing the nano-structure, the present disclosure may provide a light emitting display having high light extraction efficiency with reduced manufacturing cost by simplifying the manufacturing process in which indium-tin-oxide layer and nitride layer is deposited without any additional nano process. Accordingly, a light emitting display having high light extraction efficiency while reducing manufacturing cost is provided. Furthermore, a light emitting display capable of low-power driving by increasing the density of nano-structures and having a uniform dispersion of nano-structures, improving light extraction efficiency, and reducing power consumption is provided.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating a schematic structure of a light emitting display according to the present disclosure.

FIG. 2 is a circuit diagram illustrating a structure of one pixel included in the light emitting display according to the present disclosure.

FIG. 3 is a plan view illustrating a structure of the pixels disposed in the light emitting display according to a first embodiment of the present disclosure.

FIG. 4 is a cross-sectional view, cutting along line I-I′ in FIG. 3, for illustrating a structure of the light emitting display according to the first embodiment of the present disclosure.

FIG. 5 is a cross-sectional view, enlarging ‘X’ area marked by dotted rectangular in FIG. 4, for illustrating a structure of the light emitting display according to the first embodiment of the present disclosure.

FIG. 6 is a cross-sectional view, enlarging ‘X’ area of FIG. 4, cutting along line I-I′, for illustrating a structure of the light emitting display according to the second embodiment of the present disclosure.

FIG. 7 is a cross-sectional view, enlarging ‘X’ area in FIG. 4, cutting along line I-I′, for illustrating a structure of the light emitting display according to the third embodiment of the present disclosure.

FIG. 8 is an enlarged plan view, illustrating a structure of four sub-pixels included in one pixel disposed in the light emitting display according to the fourth embodiment of the present disclosure.

FIG. 9 is a cross-sectional view, cutting along line II-II′, illustrating a structure of the light emitting display according to the fourth embodiment of the present disclosure.

FIG. 10 is an enlarged plan view illustrating a structure of four sub-pixels included in one pixel disposed in the light emitting display according to the fifth embodiment of the present disclosure.

FIG. 11 is a cross sectional view, cutting along line III-III′ in FIG. 10, for illustrating a structure of the light emitting display according to the fifth embodiment of the present disclosure.

FIG. 12 is a cross sectional view, cutting along line I-I′ in FIG. 3, for illustrating a structure of the light emitting display according to the sixth embodiment of the present disclosure.

FIG. 13 is a cross-sectional view, enlarging ‘X’ area in FIG. 12, cutting along line I-I′ in FIG. 3, for illustrating a structure of the light emitting display according to the seventh embodiment of the present disclosure.

FIG. 14 is an enlarged plan view illustrating a structure of four sub-pixels included in one pixel disposed in the light emitting display according to the eighth embodiment of the present disclosure.

FIG. 15 is a cross-sectional view, cutting along line IV-IV′ in FIG. 14, for illustrating a structure of the light emitting display according to the eighth embodiment of the present disclosure.

FIG. 16 is an enlarged plan view illustrating a structure of four sub-pixels included in one pixel disposed in the light emitting display according to the ninth embodiment of the present disclosure.

FIG. 17 is a cross-sectional view, cutting along line V-V′ in FIG. 16, for illustrating a structure of the light emitting display according to the ninth embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

The shapes, sizes, dimensions (e.g., length, width, height, thickness, radius, diameter, area, etc.), ratios, angles, number of elements, and the like, which are illustrated in the drawings in order to describe various example embodiments of the present disclosure, are merely given by way of example. Therefore, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed there-between. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing the components of the present disclosure, terms such as ‘first,’ ‘second,’ ‘A,’ ‘B,’ ‘(a)’ and ‘(b)’ may be used. These terms are only used to distinguish the components from other components, and the nature, sequence, order or number of the corresponding component is not limited by the term. Where an element is described as being “linked,” “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts. Since a scale of each of elements shown in the accompanying drawings may be different from an actual scale for convenience of description, the present disclosure is not limited to the scale shown in the drawings.

Hereinafter, referring to the attached figures, the present disclosure will be explained. The scales of the elements shown in the drawings have different scales from actual ones for convenience of explanation, so they are not limited to the scales shown in the drawings.

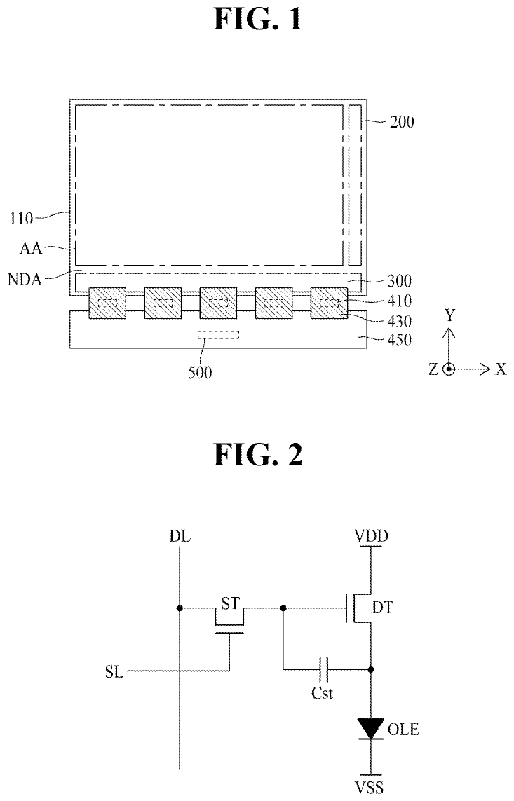

FIG. 1 is a plan view illustrating a schematic structure of an electroluminescence display according to the present disclosure. In FIG. 1, X-axis refers to the direction parallel to the scan line, Y-axis refers to the direction of the data line, and Z-axis refers to the height direction of the display device.

Referring to FIG. 1, a light emitting display comprises a substrate 110, a gate (or scan) driver 200, a data pad portion 300, a source driving IC (Integrated Circuit) 410, a flexible film 430, a circuit board 450, and a timing controller 500.

The substrate 110 may include an electrical insulating material or a flexible material. The substrate 110 may be made of a glass, a metal or a plastic, but it is not limited thereto. When the electroluminescence display is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of scan lines (or gate lines), a plurality of data lines and a plurality of pixels may be formed or disposed. Each of pixels may include a plurality of sub pixels. Each of sub pixels includes the scan line and the data line, respectively.

The non-display area NDA, which is an area not representing the video images, may be defined at the circumference areas of the substrate 110 surrounding all or some of the display area DA. In the non-display area NDA, the gate driver 200 and the data pad portion 300 may be formed or disposed.

The gate driver 200 may supply the scan (or gate) signals to the scan lines according to the gate control signal received from the timing controller 500. The gate driver 200 may be formed at the non-display area NDA at any one outside of the display area AA on the substrate 110, as a GIP (Gate driver In Panel) type. GIP type means that the gate driver 200 is directly formed on the substrate 110.

The data pad portion 300 may supply the data signals to the data line according to the data control signal received from the timing controller 500. For another example, the data driving element may be made as a driver chip and mounted on the flexible film 430. Further, the flexible film 430 may be attached at the data pad 300 which is located at the non-display area NDA of anyone outside of the display area AA on the substrate 110, as a TAB (Tape Automated Bonding) type.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (Chip On Film) or COP (Chip On Plastic) type.

The flexible circuit film 430 may include a plurality of first link lines connecting the data pad portion 300 to the source driving IC 410, and a plurality of second link lines connecting the data pad portion 300 to the circuit board 450. The flexible film 430 may be attached on the data pad portion 300 using an anisotropic conducting film, so that the data pad portion 300 may be connected to the first link lines of the flexible film 430.

The circuit board 450 may be attached to the flexible circuit film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

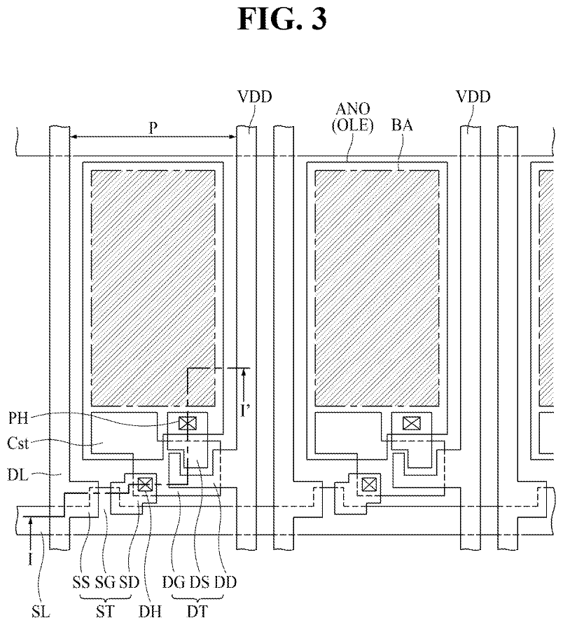

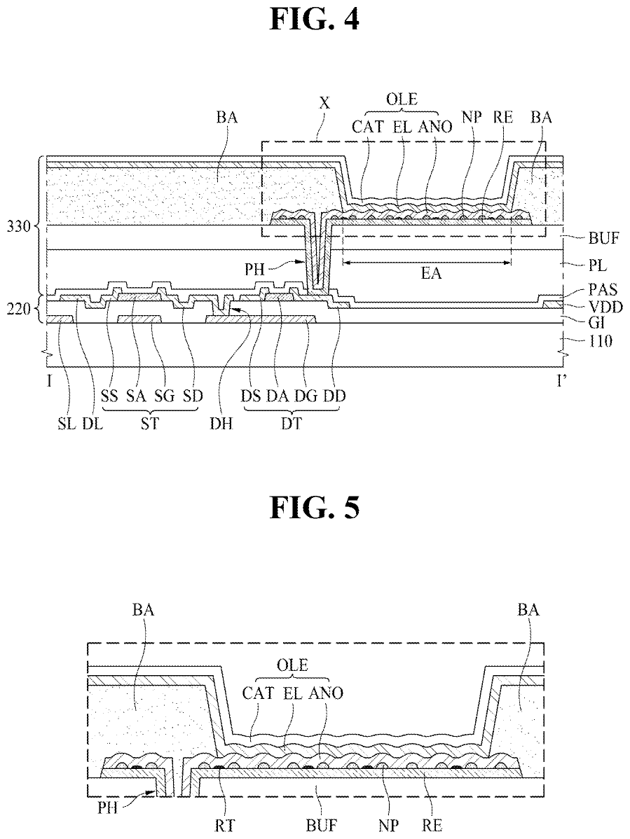

Hereinafter, referring to FIGS. 2 to 4, a preferred embodiment of the present disclosure will be explained. FIG. 2 is a circuit diagram illustrating a structure of one pixel included in the light emitting display according to the present disclosure. FIG. 3 is a plan view illustrating a structure of the pixels disposed in the light emitting display according to a first embodiment of the present disclosure. FIG. 4 is a cross-sectional view along to cutting line I-I′ in FIG. 3, for illustrating a structure of the light emitting display according to the first embodiment of the present disclosure.

Referring to FIGS. 2 to 4, one pixel P of the light emitting display may be defined by a scan line SL, a data line DL and a driving current line VDD. One pixel P of the light emitting display may include a switching thin film transistor ST, a driving thin film transistor DT, a light emitting diode OLE and a storage capacitance Cst. The driving current line VDD may be supplied with a high-level voltage for driving the light emitting diode OLE.

A switching thin film transistor ST and a driving thin film transistor DT may be formed on a substrate SUB. For example, the switching thin film transistor ST may be disposed at the portion where the scan line SL and the data line DL is crossing. The switching thin film transistor ST may include a gate electrode SG, a semiconductor layer SA, a source electrode SS and a drain electrode SD. The gate electrode SG of the switching thin film transistor ST may be connected to the scan line SL or branched from the scan line SL. The semiconductor layer SA may be disposed as crossing the gate electrode SG. The overlapped portions of the semiconductor layer SA with the gate electrode SG may be defined as the channel area. One side of the semiconductor layer SA is connected to the source electrode SS, and the other side of the semiconductor layer SA is connected to the drain electrode SD. The source electrode SS may be connected to the data line DL and the drain electrode SD may be connected to the driving thin film transistor DT. By supplying the data signal to the driving thin film transistor DT, the switching thin film transistor ST may play a role of selecting a pixel which would be driven.

The driving thin film transistor DT may play a role of driving the light diode OLE of the selected pixel by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be connected to the drain electrode SD of the switching thin film transistor ST via the drain contact hole DH penetrating the gate insulating layer GI. The semiconductor layer DA may be disposed as crossing the gate electrode DG. The overlapped area of the semiconductor layer DA with the gate electrode DG may be defined as a channel area. One side of the semiconductor layer DA is connected to the source electrode DS, and the other side of the semiconductor layer DA is connected to the drain electrode DD. The drain electrode DD may be connected to the driving current line VDD, and the source electrode DS may be connected to an anode electrode ANO of the light emitting diode OLE. A storage capacitance Cst may be disposed between the gate electrode DG of the driving thin film transistor DT and the anode electrode ANO of the light emitting diode OLE.

The driving thin film transistor DT may be disposed between the driving current line VDD and the light emitting diode OLE. The driving thin film transistor DT may control the amount of electric currents flowing to the light emitting diode OLE from the driving current line VDD according to the voltage level of the gate electrode DG of the driving thin film transistor DT connected to the switching drain electrode SD of the switching thin film transistor ST.

The light emitting diode OLE may include an anode electrode ANO, a light emitting layer EL and a cathode electrode CAT. The light emitting diode OLE may emit the light according to the amount of the electric current controlled by the driving thin film transistor DT. In other word, the light emitting diode OLE may be driven by the voltage differences between the low-level voltage and the high-level voltage controlled by the driving thin film transistor DT. The anode electrode ANO of the light emitting diode OLE may be connected to the source electrode DS of the driving thin film transistor DT, and the cathode electrode CAT may be connected to a low-level voltage line Vss where a low-level potential voltage is supplied. That is, the light emitting diode OLE may be driven by the high-level voltage controlled by the driving thin film transistor DT and the low-level voltage supplied from the low-level voltage line Vss.

On the substrate 110 having the thin film transistors ST and DT, a passivation layer PAS may be deposited. The passivation layer PAS preferably is made of an inorganic material such as a single layer made of silicon oxide (SiOx), silicon nitride (SiNx) or silicon oxynitride (SiONx), or a multilayer film thereof, etc. A planarization layer PL may be deposited on the passivation layer PAS. The planarization layer PL may be a thin film for flattening or evening the non-uniform surface of the substrate 110 on which the thin film transistors ST and DT are formed. To do so, the planarization layer PL may be made of the organic materials.

On the top surface of the planarization layer PL, a buffer layer BUF is deposited. By penetrating the planarization layer PL and the buffer layer BUF, a pixel contact hole PH is formed as exposing some of the source electrode DS of the driving thin film transistor DT.

An anode electrode ANO is formed on the buffer layer BUF, as being connected to the source electrode DS of the driving thin film transistor DT through the pixel contact hole PH. A bank BA is formed over the anode electrode ANO. The bank BA covers the edge areas of the anode electrode ANO and exposes most of the central areas to define the emission area EA. To ensure uniform luminous efficiency in the emission area EA, the bank BA may be formed to cover the pixel contact hole PH.

An emission layer EL may be deposited on the anode electrode ANO and the bank BA. The emission layer EL may be deposited over the whole surface of the display area AA on the substrate 110, as covering the anode electrodes ANO and banks BA. In the case of an organic light emitting display, the emission layer EL may include an organic material. In the case of an inorganic light emitting display, the emission layer EL may be made of an inorganic material.

For an example, the emission layer EL may include two or more stacked emission portions for emitting white light. In detail, the emission layer EL may include a first emission layer providing first color light and a second emission layer providing second color light, for emitting the white light by combining the first color light and the second color light.

In another example, the emission layer EL may include at least any one of blue-light emission layer, green-light emission layer and red-light emission layer as corresponding to the color allocated to the pixel. In addition, the light emitting diode OLE may further include at least one functional layer for enhancing the light emitting efficiency and/or the service lifetime of the emission layer EL.

The cathode electrode CAT may be disposed on the emission layer EL. The cathode electrode CAT may be stacked on the emission layer EL as being surface contact each other. The cathode electrode CAT may be formed as one sheet element over entire area of the substrate 110 as being commonly connected whole emission layers EL disposed at all pixels. In the case of the bottom emission type, the cathode electrode CAT may include metal material having excellent light reflection ratio. For example, the cathode electrode CAT may include at least any one of silver (Ag), aluminum (Al), molybdenum (Mo), gold (Au), magnesium (Mg), calcium (Ca), or barium (Ba).

A light emitting diode OLE may be formed at the emission area where the anode electrode ANO, the emission layer EL and the cathode electrode CAT are sequentially stacked. Even though it is not shown in drawings, an encapsulation layer may be further deposited on the light emitting diode OLE. The encapsulation layer may include a first inorganic encapsulation layer, an organic encapsulation layer and a second inorganic encapsulation layer, sequentially stacked each other.

In the above description referring FIG. 4, common features of the light emitting display according to the present disclosure have been mainly explained. In the following description for specific embodiments, the characteristic parts of each embodiment will be mainly explained.

### First Embodiment

Hereinafter, a detailed structure of the light emitting display according to the first embodiment of the present disclosure will be described with reference to FIG. 5, in which the light emitting diode OLE portion of FIG. 4 is enlarged. FIG. 5 is a cross-sectional view, enlarging ‘X’ area marked by dotted rectangular in FIG. 4, for illustrating a structure of the light emitting display according to the first embodiment of the present disclosure.

A driving element layer (not shown in figures) is formed on a substrate 110. A planarization layer PL is stacked on the driving element layer as covering whole are of the substrate 110. As the detailed description for the driving element layer is same with the above description referring to FIG. 4, so it will not be duplicated in the following explanation.

Referring to FIG. 5, a reflective layer RE is disposed on the buffer layer BUF having the pixel contact hole PH. As the light emitting display according to the first embodiment is a top emission type, it is preferable that the reflective layer RE is made of a metal material having excellent light reflectance. For example, the reflective layer RE may be made of silver (Ag), aluminum (Al), titanium (Ti), nickel (Ni), platinum (Pd) or an alloy thereof.

A nano structure layer is formed on the reflective layer RE. FIG. 5 illustrates a case in which the nano structure layer is made of nano-particles NP. The nano-particles NP may be randomly distributed on the surface of the reflective layer RE. The nano-particles NP are preferably formed of an oxide material including indium. For example, the nano-particles NP are made of any one of indium-tin-oxide (ITO), indium-zinc-oxide (IZO) or indium-gallium-zinc-oxide (IGZO). In particular, indium nano-particles NP are precipitated by reacting with ammonia gas (NH3), hydrogen gas (H2), oxygen gas (O2) and water molecules (H2O) or a combination thereof, in a plasma state. By this method with indium-zinc-oxide, the size of the indium nano-particles NP may be more uniform than when other oxides are used.

For example, after forming a nano-based layer having a thickness of 100 Å to 500 Å with indium-zinc-oxide, when treated with ammonia gas (NH3), hydrogen gas (H2), oxygen gas (O2) and water molecules H2O or combination thereof in a plasma state, then nano-particles NP with a diameter of 800 Å to 3,000 Å may be formed. In this case, when the nano-based layer is formed to a thin thickness of 200 Å or less, the nano-based layer almost disappears, and the nano-particles NP may be scattered on the reflective layer RE. Further, a portion of the residual layer RT may be remained between the nano-particles NP. Here, the thickness of the residual layer RT is much thinner than the thickness of the nano-based layer, and may be much smaller than the size of the nano-particles NP. Nano-particles NP may be made of the same material as the nano-based layer. In addition, the nano-particles NP may include the same material as the nano-based layer, but may have different compositions.

An anode electrode ANO is stacked on the bumpy surface where the nano-particles NP are formed. The light emitting display according to the first embodiment is a top emission type. Since the reflective layer RE is formed on the buffer layer BUF, a transparent conductive material may be stacked on the nano-particles NP. For example, the anode electrode ANO may be formed of indium-zinc-oxide, which is a material of the nano-particles NP, with indium-tin-oxide having excellent interfacial characteristics.

The reflective layer RE and the nano-particles NP may be patterned in the same shape as the anode electrode ANO. For example, after forming the reflective layer RE, the nano-particles NP may be formed, and then the material layer for the anode electrode ANO may be stacked. After that, by collectively patterning the reflective layer RE, the nano-particles NP and the material layer for the anode electrode ANO, the anode electrode ANO may be formed.

The anode electrode ANO has a shape (or, profile) that reflects the uneven cross-sectional profile of the nano-particles NP as it is. A bank BA defining the emission area EA is formed on the anode electrode ANO. An emission layer EL is stacked on the bank BA and the anode electrode ANO. Since the thickness of the emission layer EL is very thin, protrusions appearing on the surface of the anode electrode ANO may also appear on the emission layer EL as a bumpy shape, regardless of whether the emission layer EL is an organic material or inorganic material.

A cathode electrode CAT is stacked on the emission layer EL. The cathode electrode CAT may also have an uneven cross-sectional profile due to the nano-particles NP. The protrusion shape of the anode electrode ANO prevents the formation of a light waveguide between the anode electrode ANO and the cathode electrode CAT, so that the amount of light generated in the emission layer EL is extracted to the outside more than the amount of light trapped between the anode electrode ANO and the cathode electrode CAT. Accordingly, light extraction efficiency may be improved.

### Second Embodiment

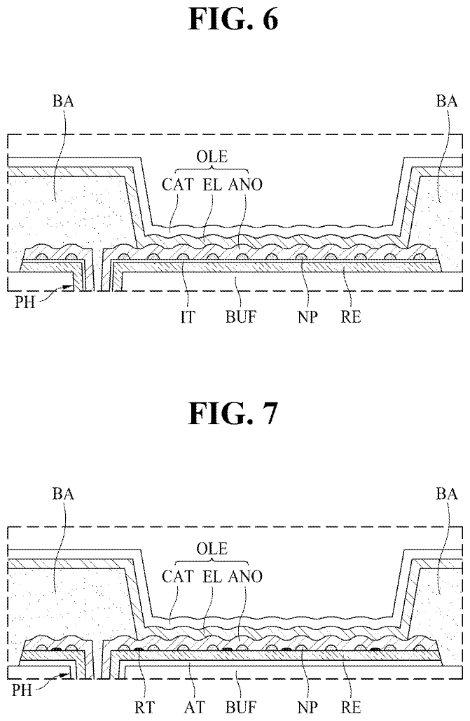

Hereinafter, referring to FIG. 6, a light emitting display according to the second embodiment of the present disclosure will be explained. FIG. 6 is a cross-sectional view, enlarging ‘X’ area of FIG. 4, cutting along line I-I′, for illustrating a structure of the light emitting display according to the second embodiment of the present disclosure.

Referring to FIG. 6, the structure of a light emitting display according to the second embodiment is very similar with that of the light emitting display according to the first embodiment. The differentiated feature of the second embodiment is that the nano-particles NP are not scattered on the reflective layer RE, but are scattered on the nano-based layer IT.

For example, a nano-based layer IT is deposited to a thickness of 300 Å or more on the reflective layer RE. The nano-particles NP are formed on the nano-based layer IT using ammonia gas (NH3), hydrogen gas (H2), oxygen gas (O2), and water molecules (H2O) or a combination thereof in s plasma state. As a result, the nano-based layer IT of about 100 Å remains, and the nano-particles NP having a diameter of 1,500 Å or more are formed on the nano-based layer IT.

An anode electrode ANO is made of a transparent conductive material on a nano layer including nano-particles NP and a nano-based layer IT. A bank BA is formed on the anode electrode ANO to define the emission area EA.

A cathode electrode CAT is deposited on the emission layer EL. The cathode electrode CAT may also have an uneven cross-sectional profile due to the nano-particles NP. The protrusion shape of the anode electrode ANO prevents the formation of a light waveguide between the anode electrode ANO and the cathode electrode CAT, so that the amount of light generated in the emission layer EL is extracted to the outside more than the amount of light trapped between the anode electrode ANO and the cathode electrode CAT. Accordingly, light extraction efficiency may be improved.

### Third Embodiment

Hereinafter, referring to FIG. 7, a light emitting display according to the third embodiment of the present disclosure will be explained. FIG. 7 is a cross-sectional view, enlarging ‘X’ area in FIG. 4, cutting along line I-I′, for illustrating a structure of the light emitting display according to the third embodiment of the present disclosure.

Referring to FIG. 7, the structure of a light emitting display according to the third embodiment is very similar with that of the light emitting display according to the first embodiment. The differentiated feature of the third embodiment is that a lower conductive layer is further included under the reflective layer RE.

For example, a lower conductive layer AT made of a transparent conductive material including indium-tin-oxide or indium-zinc-oxide is firstly deposited on the buffer layer BUF in which the pixel contact hole PH is formed. After that, a reflective layer RE is deposited, and then a nano-based layer is deposited to a thickness of 100 Å to 200 Å. In a plasma state, nano-particles NP are formed on the nano-based layer using ammonia gas (NH3), hydrogen gas (H2), oxygen gas (O2) and water molecules (H2O) or a combination thereof. As a result, the nano-based layer is almost eliminated, and nano-particles NP having a diameter of about 1,000 Å are formed on the reflective layer RE.

After the nano-particles NP are formed by reacting the nano-based layer with ammonia gas (NH3), hydrogen gas (H2), oxygen gas (O2) and water molecules (H2O) or a combination thereof in a plasma state, a residual thin layer RT may be remained. The residual thin layer RT may include the same material as the nano-particles NP. Alternatively, the residual thin layer RT may include the same material as the nano-particles NP, but may have different compositions.

An anode electrode ANO made of a transparent conductive material is formed on the nano layer including the nano-particles NP and the residual thin layer RT. For example, a transparent conductive material is deposited on the nano-particles NP and patterned to form the anode electrode ANO. At this time, the nano-particles NP under the transparent conductive material layer, the reflective layer RE, and the lower conductive layer AT are patterned together to form the same shape as the anode electrode ANO.

A bank BA is formed on the anode electrode ANO to define the emission area EA. An emission layer EL is deposited on the anode electrode ANO and the bank BA. A cathode electrode CAT is deposited on the emission layer EL. The cathode electrode CAT may also have an uneven cross-sectional profile due to the nano-particles NP.

The protrusion shape of the anode electrode ANO prevents the formation of a light waveguide between the anode electrode ANO and the cathode electrode CAT, so that the amount of light generated in the emission layer EL is extracted to the outside more than the amount of light trapped between the anode electrode ANO and the cathode electrode CAT. Accordingly, light extraction efficiency may be improved.

### Fourth Embodiment

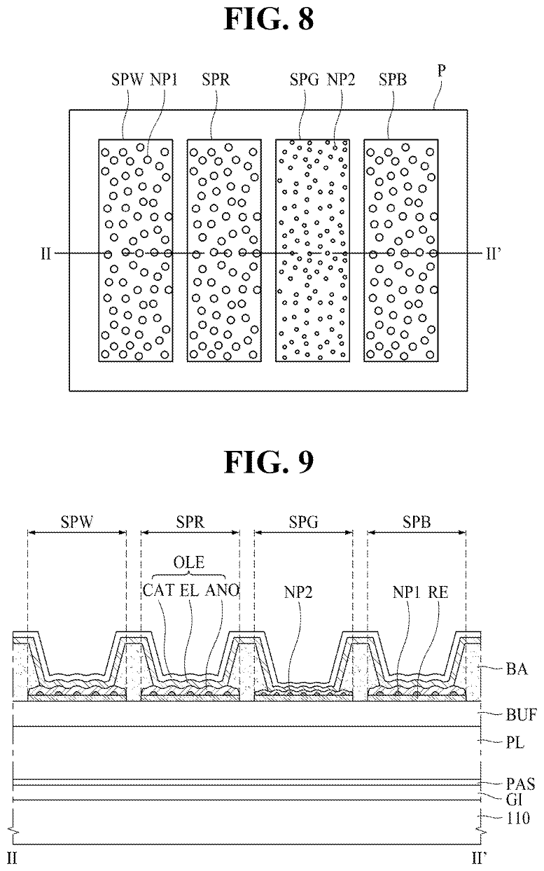

Hereinafter, referring to FIGS. 8 and 9, a light emitting display according to the fourth embodiment of the present disclosure will be explained. FIG. 8 is an enlarged plan view, illustrating a structure of four sub-pixels included in one pixel disposed in the light emitting display according to the fourth embodiment of the present disclosure. FIG. 9 is a cross-sectional view, cutting along line II-II′, illustrating a structure of the light emitting display according to the fourth embodiment of the present disclosure.

A light emitting display according to a fourth embodiment of the present disclosure includes a plurality of pixels arrayed in a matrix manner. Referring to FIG. 8, one pixel P includes four sub-pixels. For example, one pixel P may include a white sub-pixel SPW, a red sub-pixel SPR, a green sub-pixel SPG, and a blue sub-pixel SPB, but is not limited thereto, and may include sub-pixels of other colors such as purple red (magenta), cyan, yellowish green (or yellow).

Nano-particles are distributed in each sub-pixel. For example, first nano-particles NP1 having a first diameter are dispersed in the white sub-pixel SPW, the red sub-pixel SPR and the blue sub-pixel SPB. Meanwhile, second nano-particles NP2 having a second diameter smaller than the first diameter are scattered in the green sub-pixel SPG.

In detail, a driving layer may be formed on a substrate 110. The driving layer may include a gate insulating layer GI and a passivation layer PAS. On the driving layer, a light emitting layer may be disposed. The light emitting layer may include a planarization layer PL, a buffer layer BUF, a light emitting diode OLE and a bank BA.

A reflective layer RE is formed on the buffer layer BUF. For example, a reflective layer RE is separately formed on each of the four sub-pixels SPW, SPR, SPG and SPB. Nano-particles NP1 and NP2 are formed on the reflective layer RE.

For example, a nano-based layer having a thickness of 200 Å is formed at each of the white sub-pixel SPW, the red sub-pixel SPR and the blue sub-pixel SPB. Meanwhile, a nano-based layer having a thickness of 100 Å is formed at the green sub-pixel SPG. Then, in a plasma state, nano-particles are formed at the nano-based layer using ammonia gas (NH3), hydrogen gas (H2), oxygen gas (O2) and water molecules (H2O) or a combination thereof. As a result, first nano-particles NP1 having a diameter of 2,000 Å are formed in the white sub-pixel SPW, the red sub-pixel SPR and the blue sub-pixel SPB, and second nano-particles NP2 having a diameter of 1,000 Å are formed in the green sub-pixel SPG. Like this, by forming the nano-particles differently for each sub-pixel, the efficiency and color characteristics of the emission layer EL may be optimized for each color assigned to each sub-pixel.

In the above description, the case where the second nano-particles NP2 are disposed only in the green sub-pixel SPG has been explained as an example. However, it is not limited thereto. Second nano-particles NP2 having a different size from the first nano-particles NP1 may be disposed in at least one of the four sub-pixels.

Further, the four sub-pixels may include nano-particles having different size from each other. For example, first nano-particles are placed in the white sub-pixel SPW, second nano-particles are placed in the red sub-pixel SPR, third nano-particles are placed in the green sub-pixel SPG and fourth nano-particles may be disposed in the blue sub-pixel SPB. Here, the first to fourth nano-particles have different size from each other.

In the fourth embodiment, the case has been described where the second nano-particles NP2 are disposed in a specific sub-pixel with the cross-sectional structure according to the first embodiment shown in FIG. 5. However, it is not limited thereto. Nano-particles having different sizes may be disposed in at least one sub-pixel even in the case of having the cross-sectional structure according to the second embodiment or third embodiment.

### Fifth Embodiment

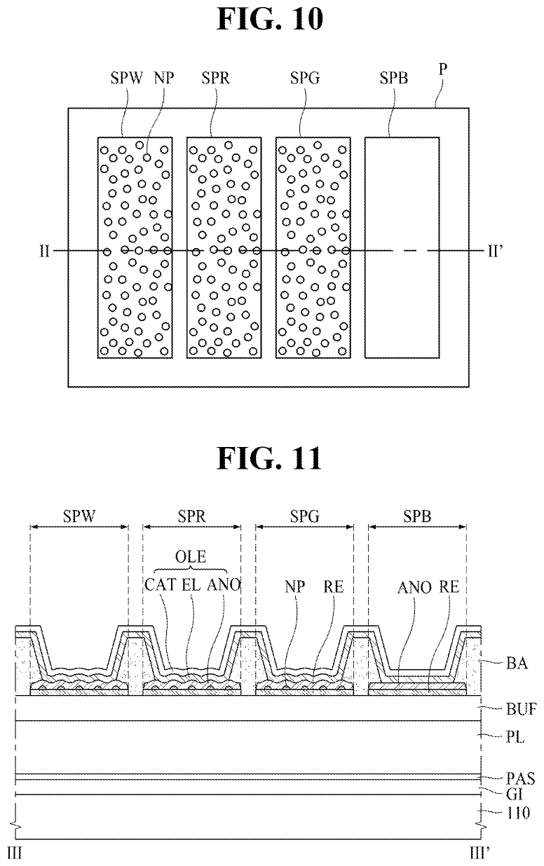

Hereinafter, referring to FIGS. 10 and 11, a light emitting display according to the fifth embodiment of the present disclosure will be explained. FIG. 10 is an enlarged plan view illustrating a structure of four sub-pixels included in one pixel disposed in the light emitting display according to the fifth embodiment of the present disclosure. FIG. 11 is a cross sectional view, cutting along line III-III′ in FIG. 10, for illustrating a structure of the light emitting display according to the fifth embodiment of the present disclosure.

A light emitting display according to a fifth embodiment of the present disclosure includes a plurality of pixels arrayed in a matrix manner. Referring to FIG. 10, one pixel P includes four sub-pixels. For example, one pixel P may include a white sub-pixel SPW, a red sub-pixel SPR, a green sub-pixel SPG, and a blue sub-pixel SPB.

Any one of the sub-pixels does not have nano-particles. For example, nano-particles NP having a certain diameter are dispersed in the white sub-pixel SPW, the red sub-pixel SPR and the green sub-pixel SPG. However, there are no nano-particles in the blue sub-pixel SPB.

A reflective layer RE is formed on the buffer layer BUF. For example, a reflective layer RE is separately formed on each of the four sub-pixels SPW, SPR, SPG and SPB. Nano-particles NP1 and NP2 are formed on the reflective layer RE. A nano-based layer having a thickness of 100 Å to 200 Å is formed at each of the white sub-pixel SPW, the red sub-pixel SPR and the green sub-pixel SPG. However, a nano-based layer is not formed on the blue sub-pixel SPB. Then, in a plasma state, nano-particles are formed at the nano-based layer using ammonia gas (NH3), hydrogen gas (H2), oxygen gas (O2) and water molecules (H2O) or a combination thereof. As a result, nano-particles NP having a diameter of 1,000 Å to 2,000 Å are formed in the white sub-pixel SPW, the red sub-pixel SPR and the green sub-pixel SPG, but no nano-particles are formed in the blue sub-pixel SPB.

In the above description, a case has been described as an example in which nano-particles are not formed only in the blue sub-pixel SPB. However, it is not limited thereto. Nano-particles may not be disposed on at least any one of the four sub-pixels.

In addition, the three sub-pixels in which the nano-particles are formed may have nano-particles of different sizes. For example, first nano-particles are placed in the white sub-pixel SPW, second nano-particles are placed in the red sub-pixel SPR, and third nano-particles are placed in the green sub-pixel SPG. However, nano-particles may not be disposed in the blue sub-pixel SPB. Here, the first to third nano-particles have different size from each other.

In the fifth embodiment, the case has been described where there is no nano-particles are disposed in a specific sub-pixel with the cross-sectional structure according to the first embodiment shown in FIG. 5. However, it is not limited thereto. No nano-particles may be disposed in at least one sub-pixel even in the case of having the cross-sectional structure according to the second embodiment or third embodiment.

### Sixth Embodiment

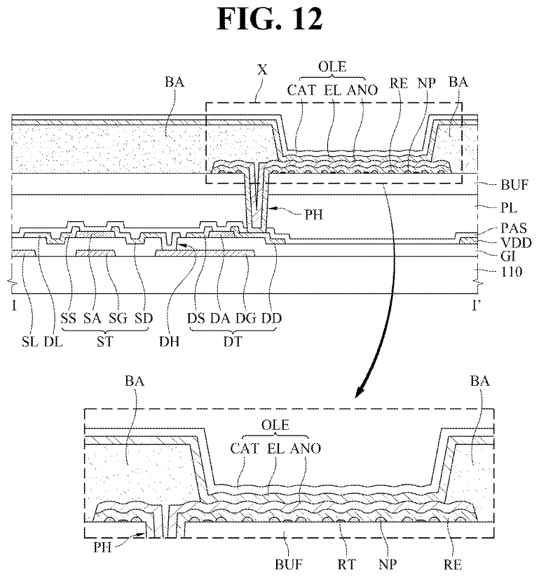

Hereinafter, referring to FIG. 12, a light emitting display according to the sixth embodiment of the present disclosure will be explained. FIG. 12 is a cross sectional view, cutting along line I-I′ in FIG. 3, for illustrating a structure of the light emitting display according to the sixth embodiment of the present disclosure.

Referring to FIG. 12, a light emitting display according to the sixth embodiment is very similar with the light emitting display according to the first embodiment. The difference is that, for the sixth embodiment, the reflective layer RE has a structure covering the nano-particles NP on the nano layer having the nano-particles NP. Therefore, the nano layer having the nano-particles NP may be formed on the buffer layer BUF.

In detail, a driving layer may be formed on a substrate 110. The driving layer may include a scan line SL, a data line DL, a driving current line VDD, a switching thin film transistor ST, a driving thin film transistor DT, a gate insulating layer GI and a passivation layer PAS. On the driving layer, a light emitting layer may be disposed. The light emitting layer may include a planarization layer PL, a buffer layer BUF, a light emitting diode OLE and a bank BA.

A nano-based layer is deposited on the buffer layer BUF with a thickness of 100 Å to 200 Å. In a plasma state, nano-particles are formed at the nano-based layer using ammonia gas (NH3), hydrogen gas (H2), oxygen gas (O2) and water molecules (H2O) or a combination thereof. As a result, the nano-based layer is almost eliminated, and nano-particles NP having a diameter of about 1,000 Å are formed on the reflective layer RE. A portion of the nano-based layer may remain as a residual thin layer RT.

A reflective layer RE is formed on the nano layer including the nano-particles NP and the residual thin layer RT. An anode electrode ANO made of a transparent conductive material is formed on the reflective layer RE. For example, a reflective layer RE is deposited on the nano-particles NP, and then depositing and patterning a transparent material an anode electrode ANO is formed. At this time, the reflective layer RE and the nano layer including the nano-particles NP which are disposed under the transparent conductive material layer, are patterned together to form the same shape as the anode electrode ANO.

A bank BA is formed on the anode electrode ANO to define the emission area EA. An emission layer EL is deposited on the anode electrode ANO and the bank BA. A cathode electrode CAT is deposited on the emission layer EL. The cathode electrode CAT may also have an uneven cross-sectional profile due to the nano-particles NP.

A protrusion shape is formed on the surface of the anode electrode ANO, and the emission layer EL interposed between anode electrode ANO and the cathode electrode CAT is not formed as a flat thin layer having a constant thickness. Therefore, there is no optical waveguide at the emission layer EL between the anode electrode ANO and the cathode electrode CAT. As a result, the amount of light generated in the emission layer EL is extracted to the outside more than the amount of light trapped between the anode electrode ANO and the cathode electrode CAT. Accordingly, light extraction efficiency may be improved.

### Seventh Embodiment

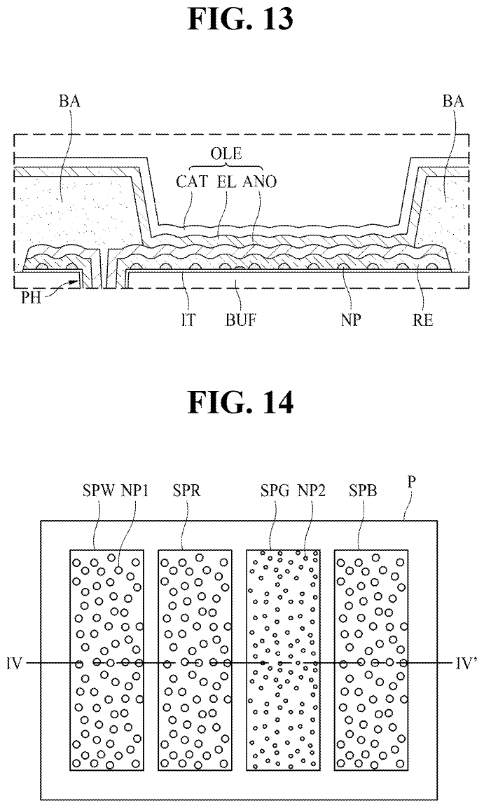

Hereinafter, referring to FIG. 13, a light emitting display according to the seventh embodiment of the present disclosure will be explained. FIG. 13 is a cross-sectional view, enlarging ‘X’ area in FIG. 12, cutting along line I-I′ in FIG. 3, for illustrating a structure of the light emitting display according to the seventh embodiment of the present disclosure.

Referring to FIG. 13, a light emitting display according to the seventh embodiment has very similar structure with the light emitting display according to the sixth embodiment. The difference is that, for the seventh embodiment, the nano-particles NP is not distributed on the reflective layer RE but on the nano-based layer IT.

For example, a nano-based layer IT is deposited to a thickness of 300 Å or more on the buffer layer BUF. In a plasma state, nano-particles NP are formed at the nano-based layer IT using ammonia gas (NH3), hydrogen gas (H2), oxygen gas (O2) and water molecules (H2O) or a combination thereof. As a result, a nano-based layer IT with a thickness of about 100 Å remains, and nano-particles NP having a diameter of 1,500 Å or more are formed on the nano-based layer IT.

A reflective layer RE is formed on the nano layer including the nano-particles NP and the nano-based layer IT. An anode electrode ANO made of a transparent conductive material is formed on the reflective layer RE. A bank BA is formed on the anode electrode ANO to define the emission area EA. An emission layer EL is deposited on the anode electrode ANO and the bank BA.

A cathode electrode CAT is deposited on the emission layer EL. The cathode electrode CAT may also have an uneven cross-sectional profile due to the nano-particles NP. A protrusion shape is formed on the surface of the anode electrode ANO, and the emission layer EL interposed between anode electrode ANO and the cathode electrode CAT is not formed as a flat thin layer having a constant thickness. Therefore, there is no optical waveguide at the emission layer EL between the anode electrode ANO and the cathode electrode CAT. As a result, the amount of light generated in the emission layer EL is extracted to the outside more than the amount of light trapped between the anode electrode ANO and the cathode electrode CAT. Accordingly, light extraction efficiency may be improved.

### Eighth Embodiment

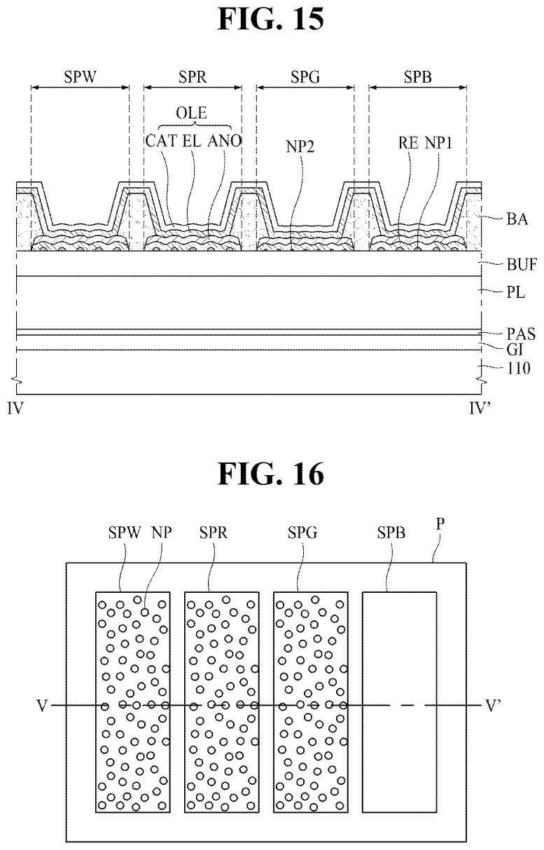

Hereinafter, referring to FIGS. 14 and 15, a light emitting display according to the eighth embodiment of the present disclosure will be explained. FIG. 14 is an enlarged plan view illustrating a structure of four sub-pixels included in one pixel disposed in the light emitting display according to the eighth embodiment of the present disclosure. FIG. 15 is a cross-sectional view, cutting along line IV-IV′ in FIG. 14, for illustrating a structure of the light emitting display according to the eighth embodiment of the present disclosure.

A light emitting display according to an eighth embodiment of the present disclosure includes a plurality of pixels arrayed in a matrix manner. Referring to FIG. 14, one pixel P includes four sub-pixels. For example, one pixel P may include a white sub-pixel SPW, a red sub-pixel SPR, a green sub-pixel SPG, and a blue sub-pixel SPB.

Nano-particles are distributed in each sub-pixel. For example, first nano-particles NP1 having a first diameter are dispersed in the white sub-pixel SPW, the red sub-pixel SPR and the blue sub-pixel SPB. Meanwhile, second nano-particles NP2 having a second diameter smaller than the first diameter are scattered in the green sub-pixel SPG.

In detail, a driving layer may be formed on a substrate 110. The driving layer may include a gate insulating layer GI and a passivation layer PAS. On the driving layer, a light emitting layer may be disposed. The light emitting layer may include a planarization layer PL, a buffer layer BUF, a light emitting diode OLE and a bank BA.

A nano layer including nano-particles NP1 and NP2 are formed on the buffer layer BUF. A reflective layer RE is deposited on the nano-particles NP1 and NP2. For example, at each of four sub-pixels SPW, SPR, SPG and SPB, the nano layer and the reflective layer RE are formed separately. An anode electrode ANO is formed on the reflective layer RE.

For example, a nano-based layer having a thickness of 200 Å is formed at each of the white sub-pixel SPW, the red sub-pixel SPR and the blue sub-pixel SPB. Meanwhile, a nano-based layer having a thickness of 100 Å is formed at the green sub-pixel SPG. Then, in a plasma state, nano-particles are formed at the nano-based layer using ammonia gas (NH3), hydrogen gas (H2), oxygen gas (O2) and water molecules (H2O) or a combination thereof. As a result, first nano-particles NP1 having a diameter of 2,000 Å are formed in the white sub-pixel SPW, the red sub-pixel SPR and the blue sub-pixel SPB, and second nano-particles NP2 having a diameter of 1,000 Å are formed in the green sub-pixel SPG. Like this, by forming the nano-particles differently for each sub-pixel, the efficiency and color characteristics of the emission layer EL may be optimized for each color assigned to each sub-pixel.

A reflective metal material is deposited on the first nano-particles NP1 and the second nano-particles NP2. A transparent conductive material is deposited on the reflective metal material. After that, by patterning the transparent conductive material, an anode electrode ANO is formed. Here, the reflective metal material and the nano layer including the first nano-particles NP1 and the second nano-particles NP2 are patterned together.

At least one of four sub-pixels may include second nano-particles NP2 having different size from the first nano-particles NP1 which is disposed in the other sub-pixels. Alternatively, each of four sub-pixels may have nano-particles of different sizes, respectively. For example, first nano-particles are placed in the white sub-pixel SPW, second nano-particles are placed in the red sub-pixel SPR, third nano-particles are placed in the green sub-pixel SPG and fourth nano-particles may be disposed in the blue sub-pixel SPB. Here, the first to fourth nano-particles have different size from each other.

In the eighth embodiment, the case has been described where the second nano-particles NP2 are disposed in a specific sub-pixel with the cross-sectional structure according to the sixth embodiment shown in FIG. 12. However, it is not limited thereto. Nano-particles having different sizes may be disposed in at least one sub-pixel even in the case of having the cross-sectional structure according to the seventh embodiment.

### Ninth Embodiment

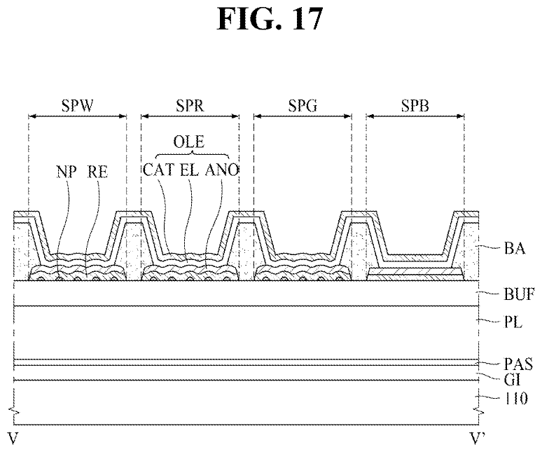

Hereinafter, referring to FIGS. 16 and 17, a light emitting display according to the ninth embodiment of the present disclosure will be explained. FIG. 16 is an enlarged plan view illustrating a structure of four sub-pixels included in one pixel disposed in the light emitting display according to the ninth embodiment of the present disclosure. FIG. 17 is a cross-sectional view, cutting along line V-V′ in FIG. 16, for illustrating a structure of the light emitting display according to the ninth embodiment of the present disclosure.

A light emitting display according to a ninth embodiment of the present disclosure includes a plurality of pixels arrayed in a matrix manner. Referring to FIG. 16, one pixel P includes four sub-pixels. For example, one pixel P may include a white sub-pixel SPW, a red sub-pixel SPR, a green sub-pixel SPG, and a blue sub-pixel SPB.

Nano-particles NP having a certain diameter are dispersed in the white sub-pixel SPW, the red sub-pixel SPR and the green sub-pixel SPG. However, there are no nano-particles in the blue sub-pixel SPB.

For example, a nano-based layer having a thickness of 100 Å to 200 Å is formed at each of the white sub-pixel SPW, the red sub-pixel SPR and the green sub-pixel SPG. However, a nano-based layer is not formed on the blue sub-pixel SPB. Then, in a plasma state, nano-particles are formed at the nano-based layer using ammonia gas (NH3), hydrogen gas (H2), oxygen gas (O2) and water molecules (H2O) or a combination thereof. As a result, nano-particles NP having a diameter of 1,000 Å to 2,000 Å are formed in the white sub-pixel SPW, the red sub-pixel SPR and the green sub-pixel SPG, but no nano-particles are formed in the blue sub-pixel SPB.

On the buffer layer, a reflective layer RE is formed on the nano-particles NP formed at the white sub-pixel SPW, the red sub-pixel SPR, and the green sub-pixel SPG except for the blue sub-pixel SPB. In addition, at the blue sub-pixel SPB, the reflective layer RE is only formed on the buffer layer BUF. In each of four sub-pixels, an anode electrode ANO is formed on the reflective layer RE.

In the above description, a case has been described as an example in which nano-particles are not formed only in the blue sub-pixel SPB. However, it is not limited thereto. Nano-particles may not be disposed on at least any one of the four sub-pixels.

In addition, the three sub-pixels in which the nano-particles are formed may have nano-particles of different sizes. For example, first nano-particles are placed in the white sub-pixel SPW, second nano-particles are placed in the red sub-pixel SPR, and third nano-particles are placed in the green sub-pixel SPG. However, nano-particles may not be disposed in the blue sub-pixel SPB. Here, the first to third nano-particles have different size from each other.

In the ninth embodiment, the case has been described where there is no nano-particles are disposed in a specific sub-pixel with the cross-sectional structure according to the sixth embodiment shown in FIG. 12. However, it is not limited thereto. No nano-particles may be disposed in at least one sub-pixel even in the case of having the cross-sectional structure according to the seventh embodiment.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims. Accordingly, the claims are not limited by the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display comprising:
a substrate including a first pixel and a second pixel;
a buffer layer on the substrate;
a nano layer on the buffer layer;
an anode electrode on the nano layer; and
a reflective layer between the buffer layer and the anode electrode.

2. The light emitting display according to claim 1, wherein the reflective layer covers the nano layer, and disposed under the anode electrode.

3. The light emitting display according to claim 1, wherein the reflective layer is disposed under the nano layer and on the buffer layer.

4. The light emitting display according to claim 3, further comprising:
a lower conductive layer disposed between the reflective layer and the buffer layer.

5. The light emitting display according to claim 4, wherein the lower conductive layer comprises: a transparent conductive material including indium-tin-oxide.

6. The light emitting display according to claim 4, wherein the lower conductive layer comprises: a transparent conductive material including indium-zinc-oxide.

7. The light emitting display according to claim 1, wherein the nano layer includes:
first nano-particles having a first size; and
second nano-particles having a second size smaller than the first size.

8. The light emitting display according to claim 1, further comprising: a third pixel on the substrate,
wherein there is no nano layer at the third pixel.

9. The light emitting display according to claim 1, wherein the nano layer includes at least one of indium-tin-oxide and indium-zinc-oxide.

10. The light emitting display according to claim 9, wherein the oxide including indium includes at least one of indium-tin-oxide, indium-zinc-oxide, indium-gallium-oxide (IGO) and indium-gallium-zinc-tin-oxide (IGZTO).

11. The light emitting display according to claim 2, wherein the nano layer includes:
a nano-based layer; and
nano-particles having protrusion shape formed on the nano-based layer.

12. The light emitting display according to claim 11, wherein the nano-based layer and the nano-particles include a same material.

13. The light emitting display according to claim 1, wherein the nano layer includes:
a plurality of nano-particles, adjacent nano-particles of the plurality of nano-particles having spaces therebetween; and
residual thin layers dispersed in the spaces between the adjacent nano-particles.

14. The light emitting display according to claim 12, wherein thickness of the residual thin layers is far less than a thickness of the nano-particles.

15. The light emitting display according to claim 12, wherein the residual thin layers include a same material as the plurality of nano-particles.

16. The light emitting display according to claim 1, further comprising:
a planarization layer under the buffer layer.

17. The light emitting display according to claim 16, further comprising:
a driving layer disposed between the planarization layer and the substrate, and including driving element coupled to the anode electrode.

18. The light emitting display according to claim 1, further comprising:
a bank covering edge portions of the anode electrode, exposing central area of the anode electrode, and defining an emission area;
an emission layer on the bank and the anode electrode; and
a cathode electrode on the emission layer.
